(19) United States
(12) Patent Application Publication
(10) Pub. No.: US 2006/0255359 A1
(43) Pub. Date: Nov. 16, 2006

(54) Light emitting diode light source model

(75) Inventors: Tseng-Bao Sun, Taichung (TW); Ko-Hsin Lee, Sindian City (TW); Yong-Yuan Xu, Xiamen City (CN)

Correspondence Address: NIKOLAI & MERSEREAU, P.A., 900 SECOND AVENUE SOUTH, SUITE 820, MINNEAPOLIS, MN, 55402, US

(73) Assignee: Quasar Optoelectronics, Inc., Taichung Hsien (TW)

(21) Appl. No.: 11/252,282

(22) Filed: Oct. 17, 2005

(30) Foreign Application Priority Data
May 11, 2005 (TW) 094207598

(51) Int. Cl. H01L 33/00

(52) U.S. Cl. 257/100

(57) ABSTRACT

An LED light source model has a substrate, at least one bare LED chip, a transparent layer and an optical light collecting element. The substrate has a top face, a bottom face and at least one chip cup defined on the top face. The at least one LED chip is mounted in the at least one chip cup. The transparent layer is formed on the top face to seal the at least one chip cup. The optical light collecting element is mounted on the top face to collect the light from each chip cup to increase the light intensity. A plurality of fins or recesses are formed or defined on the bottom face to increase a heat dissipation area. When each bare LED chip is in operation mode, heat from the bare LED chip will be conducted to the bottom face and then dissipate to the ambient air quickly.

### BACKGROUND OF THE INVENTION

1. Field of the Invention

The present invention relates to a light emitting diode light (LED) source model, and more particularly to a light emitting diode light source model having a high light intensity, simple structure and high heat dissipation etc. capabilities.

2. Description of Related Art

The light emitting diode (LED) element is widely used to be a light source of the lamps or illumination devices since the LED element has low power consumption and high enough light intensity. However, the heat from the LED element in operation mode effects the reliability of the LED element. Therefore, many companies or factories in this technology field make efforts in finding or inventing some solutions to decrease the heat influence and also devote research to increase light intensity of the LED element.

With reference to FIG. 6, an LED type bulb (50) having good heat dissipation capability has a casing (51) with a top opening (511), a PCB (52), a plurality of LED elements (53), a heat sink (54), and a top cover (55).

The PCB (52) is mounted in the casing (51) and close to the top opening (511). The heat sink (54) is also mounted in the casing (51) and touches the PCB (52) to provide a way to dissipate the heat from the LED elements (53) in an operation mode. The plurality of LED elements (53) are mounted on the PCB (52). The top cover (55) is transparent and covers the top opening (511) of the casing (51).

When the LED elements (53) are lit, heat will be conducted to the heat sink (54) in the casing (51) through the PCB (52). Since the heat sink (54) is added, the LED type bulb (50) has good heat dissipation capability. However, those many elements occupy too much space and cause a complex structure. Using the heat dissipation solution of the LED type bulb is not suitable for the flat and plane lamp or illumination devices.

Therefore, the present invention provides an LED light source model to provide another heat dissipation solution and also to effectively increase the light intensity.

### SUMMARY OF THE INVENTION

The main objective of the present invention is to provide an LED light source model suitable for flat and plane light source lamps or illumination devices that has good heat dissipation and high light intensity.

The LED light source model has a substrate, at least one bare LED chip, a transparent layer and an optical light collecting element. The substrate has a top face, a bottom face and at least one chip cup defined on the top face. The at least one LED chip is mounted in the corresponding chip cup. The transparent layer is formed on the top face to seal the chip cup. The optical light collecting element is further mounted on the top face to collect the light from each chip cup to increase the light intensity. In addition, a plurality of fins or recesses are formed or defined on the bottom face of the substrate to increase a heat dissipation area. When the at least one bare LED chip is in operation mode, heat from the bare LED chip will be conducted to the bottom face and then dissipate to the ambient air quickly.

Other objectives, advantages and novel features of the invention will become more apparent from the following detailed description when taken in conjunction with the accompanying drawings.

### BRIEF DESCRIPTION OF THE DRAWINGS

FIG. 1 is a cross sectional view of a first embodiment of an LED light source model in accordance with the present invention;

FIG. 2 is an exploded perspective view of a second embodiment of an LED light source model in accordance with the present invention;

FIG. 3 is a cross sectional view of the second embodiment of the LED light source model in accordance with the present invention;

FIG. 4 is a perspective view of a third embodiment of the LED light source model in accordance with the present invention;

FIG. 5 is an exploded perspective view of a fourth embodiment of the LED light source model in accordance with the present invention; and

FIG. 6 is a cross sectional view of a conventional LED type bulb in accordance with the prior art.

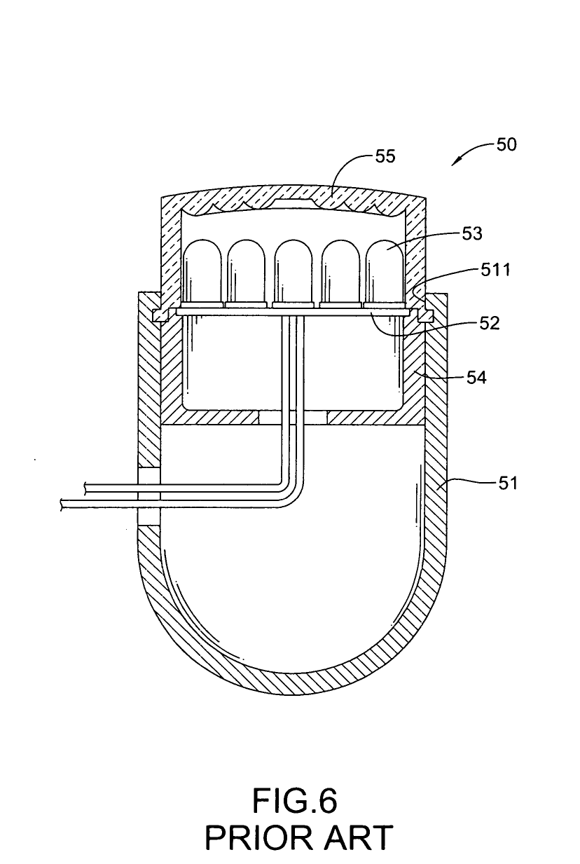

### DETAILED DESCRIPTION OF THE PREFERRED EMBODIMENT

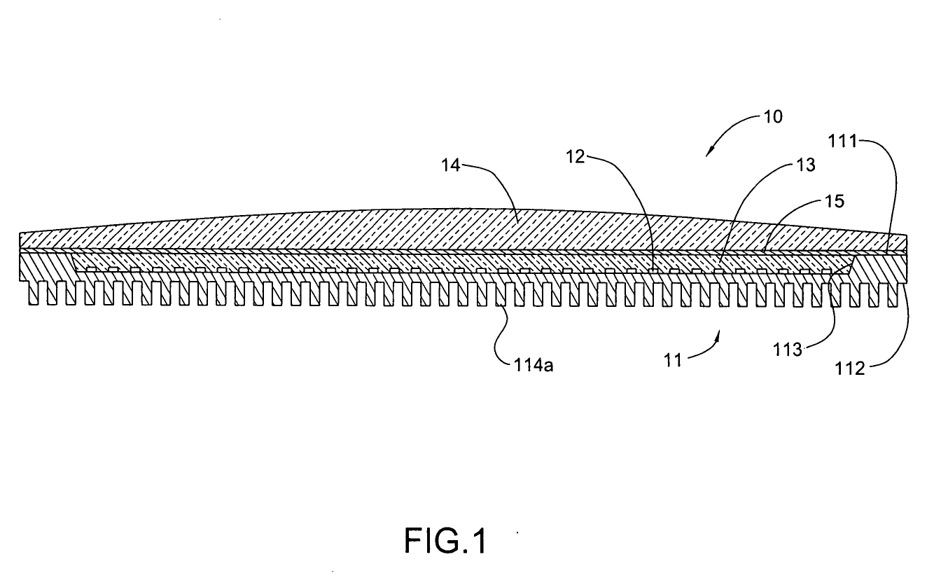

With reference to FIG. 1, a first embodiment of an LED light source model (10) in accordance with the present invention has a substrate (11) with high thermal conductivity, at least one bare LED chip (12), a transparent protection layer (13), and an optical light collecting element (14).

Since the substrate (11) has high thermal conductivity, the substrate (11) can be made of metal material (such as aluminum, copper, alloy or the like etc.) or nonmetal (such as a ceramics or the like). The substrate (11) has a top face (111), a bottom face (112), at least one chip cup (113) is defined on the top face (111) and a plurality of fins (114a) or recesses are formed on or defined in the bottom face (112). The chip cup (113) is able to be defined as a cone shape. The fins (114a) or the recesses are formed to increase the heat dissipation area of the substrate (11). The fins (114a) are formed as straight shapes and arranged parallel to each other on the bottom face. Therefore, the substrate (11) is also a heat sink.

The bare LED chip (12) is mounted in the corresponding chip cup (113) and the transparent protection layer (13) is formed on the top face (111) of the substrate (11) to seal the chip cup (113).

The optical light collecting element (14) is mounted on the top face (111) of the substrate (11) to collect light from the chip cup (113) to increase the light intensity. The optical light collecting element (14) can be an optical lens. The optical light collecting element (14) is mounted on the top face (111) through transparent glue (15) or mechanical bonding means, such as a screw means.

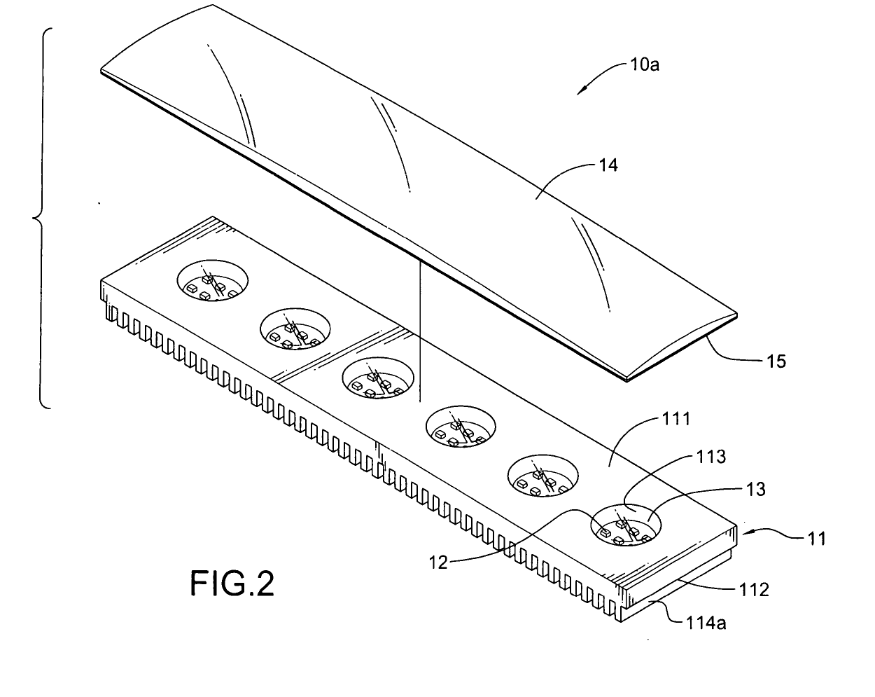

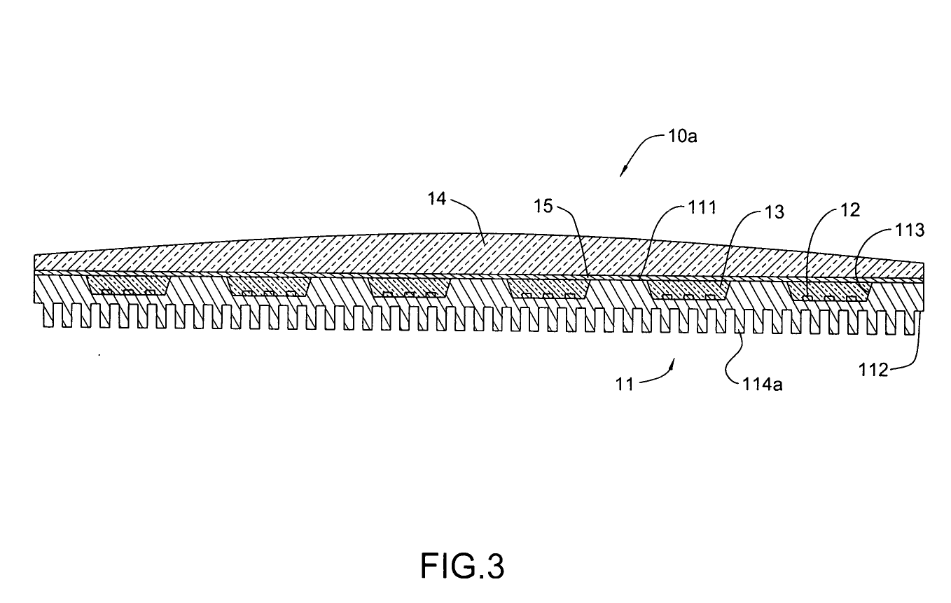

With reference to FIGS. 2 and 3, a second embodiment of an LED light source model (10a) in accordance with the present invention has a plurality of chip cups (113) defined in the top face (111) of the substrate (11). A plurality of bare LED chips (12) are mounted in each chip cup (113).

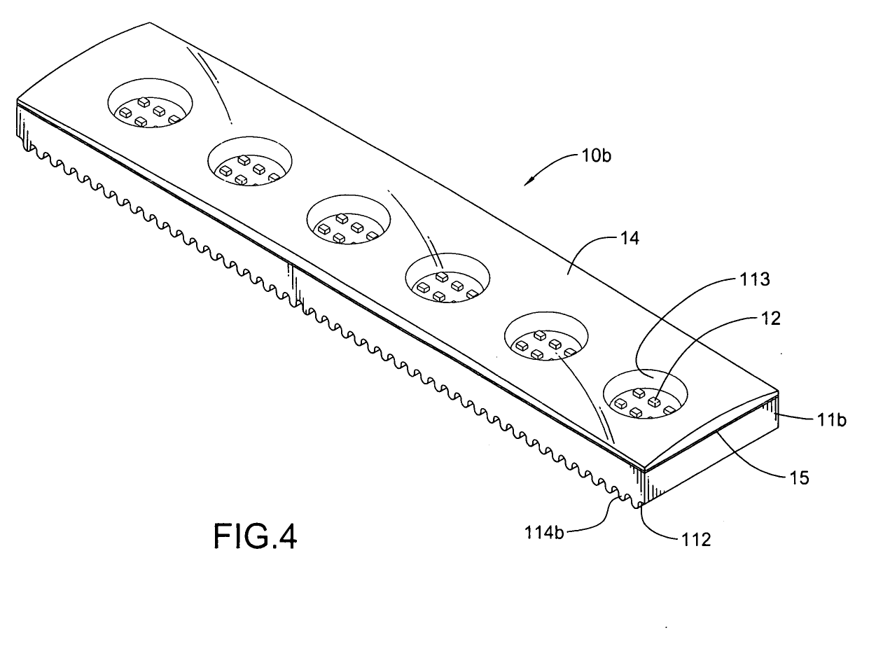

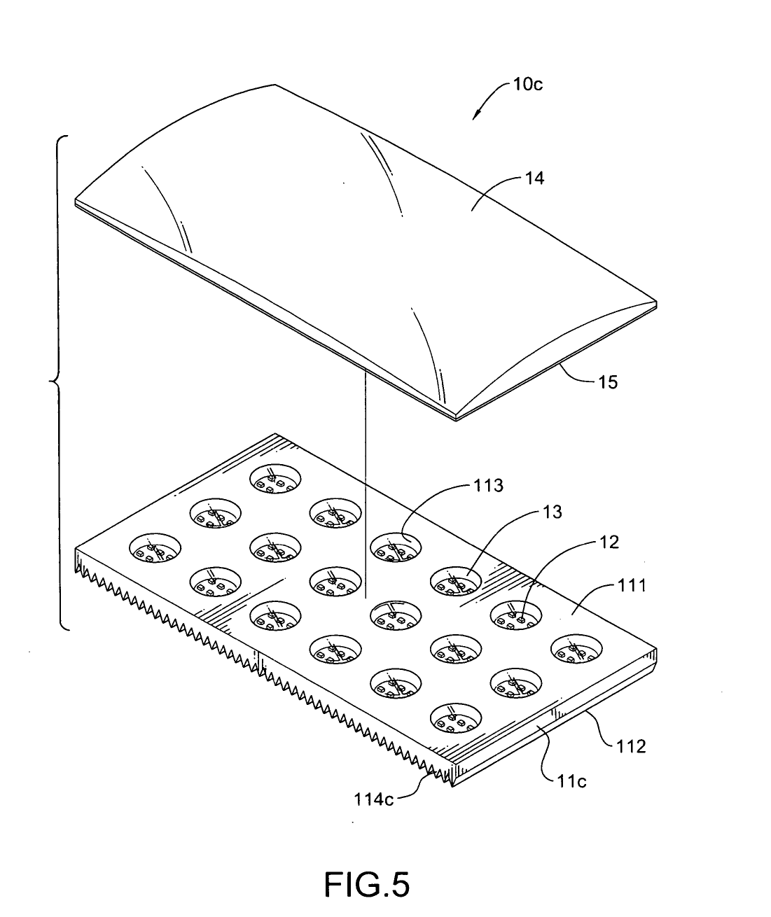

With reference to FIGS. 4 and 5, third and fourth embodiments of an LED light source model (10b, 10c) have different substrates (11b, 11c). The fins (114b) of the substrate (11b) in FIG. 4 are formed as wave shapes and are also arranged parallel to each other on the bottom face of the substrate. The fins (114c) of the substrate (11c) in FIG. 5 are formed as saw tooth shapes and are also arranged parallel on the bottom face of the substrate. In addition, the plurality of fins also can be formed as a grid.

In FIG. 5, the plurality of chip cups (113) are defined in the top face (111c) of the substrate (11c) and arranged in a matrix.

Since the substrate is flat and has high thermal conductivity, heat from the bare chips in an operation mode will be conducted to the bottom face and the LED light source model is suitable for a plane lamp or illumination device. The fins or recesses are formed or defined on the bottom whereby the heat can be dissipated to the ambient air quickly. In addition, the optical light collecting elements are mounted on the top face of the substrate such that the lights from each chip cup can be effectively collected. Therefore, the light intensity of the LED light source model is increased. Since the substrate is a chip carrier and also a heat sink, the structure of the LED light source is simple.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. An LED light source model, comprising:
a substrate having a top face, a bottom face and at least one chip cup;
at least one bare LED chip mounted in each one of the at least one chip cup;
a transparent protection layer formed on the top face of the substrate to seal the at least one chip cup; and
an optical light collecting element mounted on the top face of the substrate.

2. The LED light source model as claimed in claim 1, further comprising a plurality of fins formed on the bottom face of the substrate.

3. The LED light source model as claimed in claim 1, further comprising a plurality of recesses defined on the bottom face of the substrate.

4. The LED light source model as claimed in claim 1, wherein the optical light collecting element is an optical lens.

5. The LED light source model as claimed in claim 2, wherein each fin is formed as a straight shape.

6. The LED light source model as claimed in claim 2, wherein each fin is formed as a wave shape.

7. The LED light source model as claimed in claim 2, wherein each fin is formed as a saw tooth shape.

8. The LED light source model as claimed in claim 1, wherein the substrate is made of metal material.

9. The LED light source model as claimed in claim 1, wherein the substrate is made of nonmetal material with high thermal conductivity.

10. The LED light source model as claimed in claim 1, wherein each one of the at least one chip cup is defined as a cone shape.
